(19) United States
(12) Patent Application Publication
(10) Pub. No.: US 2015/0155824 A1
(43) Pub. Date: Jun. 4, 2015

(54) METHOD FOR MANUFACTURING SOLAR CELL AND SOLAR CELL MADE THEREBY

(71) Applicant: Chiun Mai Communication Systems, Inc., New Taipei (TW)

(72) Inventor: HOW-WEN CHIEN, New Taipei (TW)

(21) Appl. No.: 14/519,369

(22) Filed: Oct. 21, 2014

(30) Foreign Application Priority Data
Nov. 29, 2013 (CN) 201310624466.4

(51) Int. Cl. H02S 40/22; H01L 51/44; H01L 31/18; H01L 31/054

(52) U.S. Cl. CPC H02S 40/22; H01L 31/0543; H01L 51/447; H01L 31/18

(57) ABSTRACT

A method for manufacturing a solar cell including a solar cell panel having a light receiving surface and an optical film formed on the light receiving surface includes providing a solar cell panel comprising a light receiving surface, preparing a coating solution comprising a birefringent material having a relative refraction index of about 1.05 to about 2.5, a transparent adhesive, and an organic solvent, coating the light receiving surface with the coating solution, thereby forming a liquid layer of the coating solution on the light receiving surface, and curing the liquid layer to form an optical film on the light receiving surface. Light-absorbing efficiencies of the solar cell under non-zero light incident angles on the light receiving surface are increased.

### FIELD

The present disclosure relates to a method for solar cell manufacture.

### BACKGROUND

Solar cell panels are photoelectric conversion devices. A low reflection and high absorption of light on the solar cell panels is needed to achieve an improved photoelectric conversion efficiency.

### BRIEF DESCRIPTION OF THE DRAWINGS

Implementations of the present technology will now be described, by way of example only, with reference to the attached figures.

FIG. 1 is a cross-sectional view of a solar cell according to an exemplary embodiment.

FIG. 2 is a cross-sectional view showing an operating principle of an optical film of the solar cell of FIG. 1.

FIG. 3 is a diagram showing light-absorbing efficiencies of the same solar cell panel tested before and after a formation of the optical film of FIG. 1, under a light incident angle of about 0°.

FIG. 4 is a diagram showing light-absorbing efficiencies of the same solar cell panel tested before and after a formation of the optical film of FIG. 1, under a light incident angle of about 15°.

FIG. 5 is a diagram showing light-absorbing efficiencies of the same solar cell panel tested before and after a formation of the optical film of FIG. 1, under a light incident angle of about 30°.

FIG. 6 is a diagram showing improvements of light-absorbing efficiencies of a solar cell panel having the optical film of FIG. 1 relative to the solar cell panel before forming the optical film, under different light incident angles.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “comprising,” when utilized, means “including, but not necessarily limited to”; it specifically indicates open-ended inclusion or membership in the so-described combination, group, series and the like.

The term “incident angle”, when utilized, indicates an angle between a ray of light incident on a surface and the line perpendicular to the surface at the point of incidence.

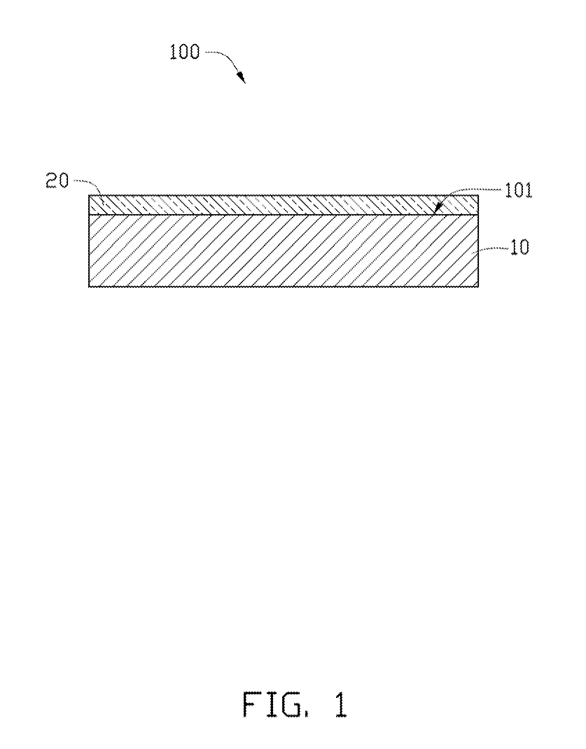

A method for manufacturing a solar cell 100 as shown in FIG. 1 according to an exemplary embodiment can comprise the following steps.

A solar cell panel 10 is provided. The solar cell panel 10 can be any type of solar cell panel, such as a silicon semiconductor solar cell panel, a cadmium telluride (CdTe) thin film solar cell panel, a copper indium gallium selenide (CIGS) thin film solar cell panel, a III-V compound semiconductor solar cell panel, or an organic material solar cell panel. A silicon semiconductor solar cell panel can comprise monocrystalline silicon solar cell panel, polycrystalline silicon solar cell panel, and amorphous silicon solar cell panel. The solar cell panel 10 comprises a light receiving surface 101 configured to receive irradiation of sunlight. The light receiving surface 101 can be a planar surface. Alternatively, the light receiving surface 101 can be etched to be a randomly rough surface. In other embodiments, the light receiving surface 101 can be a surface covered by regular three-dimensional structures, such as regular pyramidic or hemispherical structures.

A coating solution is prepared. The coating solution comprises a birefringent material, a binder, and an organic solvent.

The birefringent material has a relative refraction index in a range from about 1.05 to about 2.5. The birefringent material can be a liquid crystal. The liquid crystal can be a liquid crystal polymer (LCP). In other embodiments, the birefringent material can be one or more selected from a group consisting of quartz, calcite, and ruby. If the birefringent material is selected from quartz, calcite, and ruby, the birefringent materials are particles having a shape similar to a shape of the liquid crystal molecules which are substantially rod-shaped or oval. The particles of the birefringent material have a grain diameter no larger than 1 μm. Within the coating solution, the birefringent material can have different weight percentage ranges according to different birefringent materials, but within a range from about 0.1% to about 33%. If the birefringent material is liquid crystal, the birefringent material has a weight percentage in a range from about 0.1% to about 5% based on a total weight of the coating solution.

The binder can be ultraviolet-curable resin adhesive or thermosetting resin adhesive. The organic solvent is transparent, such as propylene glycol monomethyl ether acetate (PGMEA).

The light receiving surface 101 is coated using the coating solution, thereby forming a liquid layer of the coating solution on the light receiving surface 101. Methods for forming the liquid layer comprise but are not limited to being dip-coating, spin coating, and spray-coating. The liquid layer can have a thickness in a range from about 5 nm to about 800 μm. For the same kind of birefringent material, the thickness of the liquid layer decreases commensurate with increase of weight percentage of the birefringent material within the coating solution.

The liquid layer of the coating solution is cured to form an optical film 20 on the light receiving surface 101. Curing method can be determined according to type of the binder. For example, if the binder is ultraviolet-curable resin adhesive, the liquid layer can be cured by ultraviolet irradiation. The liquid layer can be cured under a nitrogen atmosphere. The optical film 20 can have a thickness of about 1 nm to about 500 μm. The optical film 20 essentially consists of the birefringent material and transparent adhesive. The solvent in the liquid layer is volatilized during the curing.

A weight percentage of the birefringement material greater than 33% within the coating solution or a thickness of the optical film 20 greater than 500 μm may reduce a light-transmission rate of the optical film 20.

The method can further comprise cleaning the light receiving surface 101 before forming the liquid layer of the coating solution on the light receiving surface 101.

The solar cell 100 created by the above method comprises the solar cell panel 10 and the optical film 20 formed on the light receiving surface 101 of the solar cell panel 10.

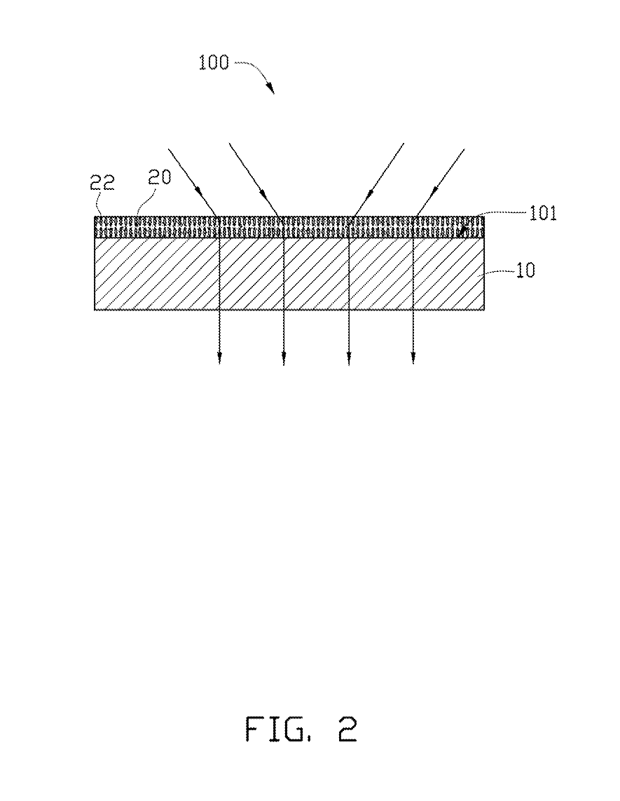

The optical film 20 comprises birefringent material 22 having a relative refraction index of about 1.05 to about 2.5. FIG. 2 shows that the birefringent material 22 changes a transmission direction of light and enables non-perpendicular incident light beams to pass through the optical film 20 to be perpendicularly incident on the light receiving surface 101, thereby reducing a reflection of the incident light and encouraging relatively more light to be absorbed by the solar cell panel 10. As such, light-absorbing efficiencies of the solar cell 100 under non-zero light incident angles are improved, thereby improving an average light-absorbing efficiency of solar cell 100.

### EMBODIMENT 1

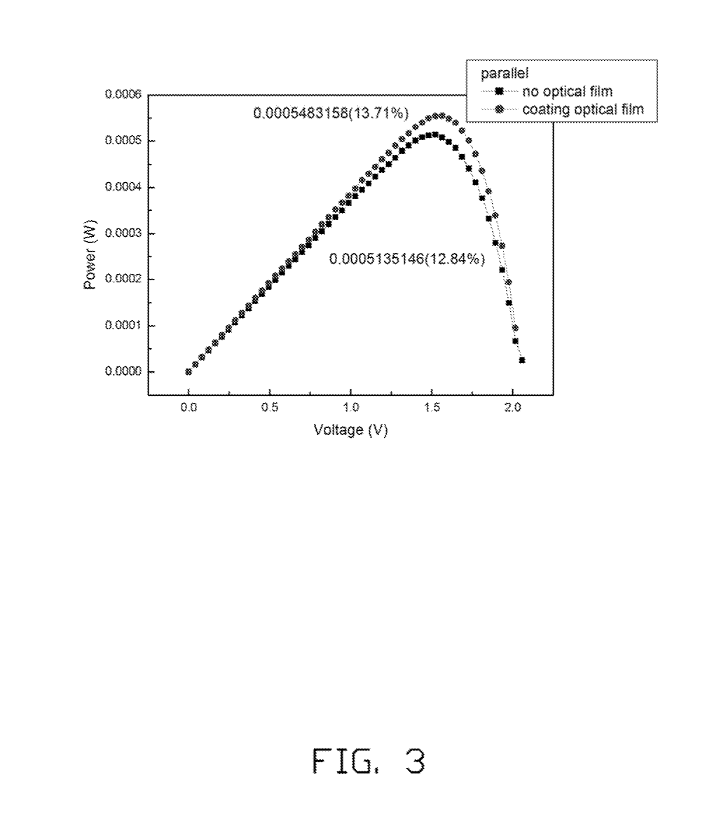

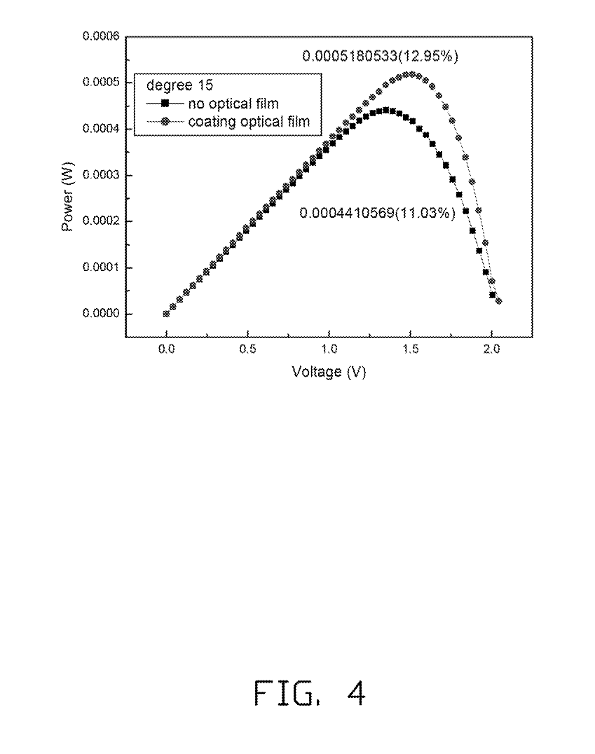

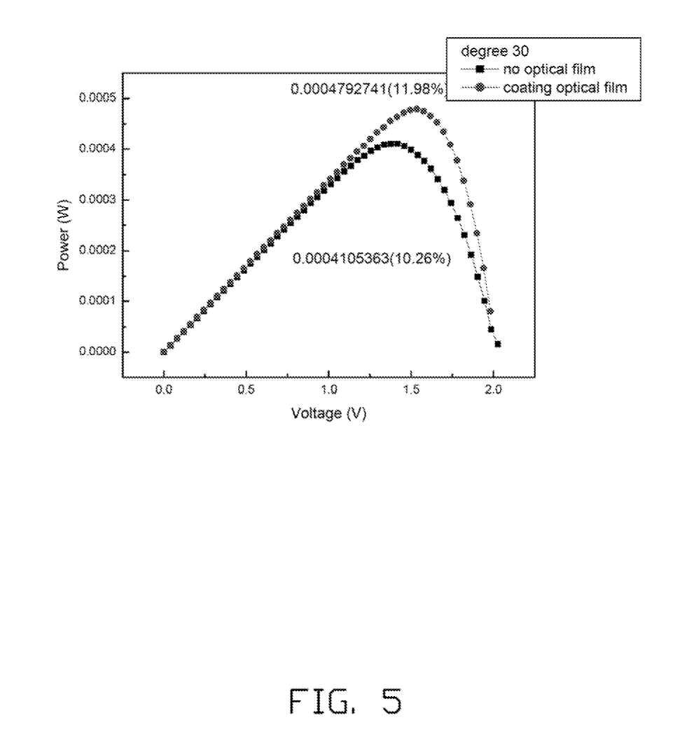

A III-V compound semiconductor solar cell panel having a planar light receiving surface is provided. Light-absorbing efficiencies of the III-V compound semiconductor solar cell panel under incident light of zero angle (meaning light beams are parallel to a normal of the light receiving surface), of 15°, and of 30° are tested and results are shown in FIGS. 3-5.

The light receiving surface is cleaned.

A coating solution is prepared. The coating solution consists of LCP, ultraviolet-curable resin adhesive, and PGMEA. The LCP has a weight percentage of about 1% within the coating solution.

The coating solution is coated on the light receiving surface by spin coating, thereby forming a liquid layer on the light receiving surface. Spin coating the liquid layer comprises the steps of first, rotating the III-V compound semiconductor solar cell panel at 500 revolutions per minute for about 10 seconds, allowing the coating solution to completely cover the light receiving surface. Second, rotating the III-V compound semiconductor solar cell panel at 3000 revolutions per minute for about 30 seconds, to create a uniform thickness of the liquid layer of the coating solution.

The liquid layer of the coating solution is cured. During curing of the liquid layer, the III-V compound semiconductor solar cell panel having the liquid layer is heat treated at 100° C. for about 80 seconds, enabling the PGMEA to be volatilized. The heat-treated III-V compound semiconductor solar cell panel is then hardened to become the light-guiding film, by ultraviolet irradiation under a wavelength of about 365 nm and power of about 8 watts for about 3 minutes. The treated III-V compound semiconductor solar cell panel is hardened under a nitrogen atmosphere.

Tests and Results:

The light-absorbing efficiencies of the sample created by the above method, at incident light angles of zero (meaning light beams are parallel to a normal of the light receiving surface), of 15°, and of 30° are tested and results are shown in FIGS. 3-5. The results show that the light-absorbing efficiencies of the sample having the optical film under each of the stated incident light angles are improved greatly relative to that of the sample before forming the optical film.

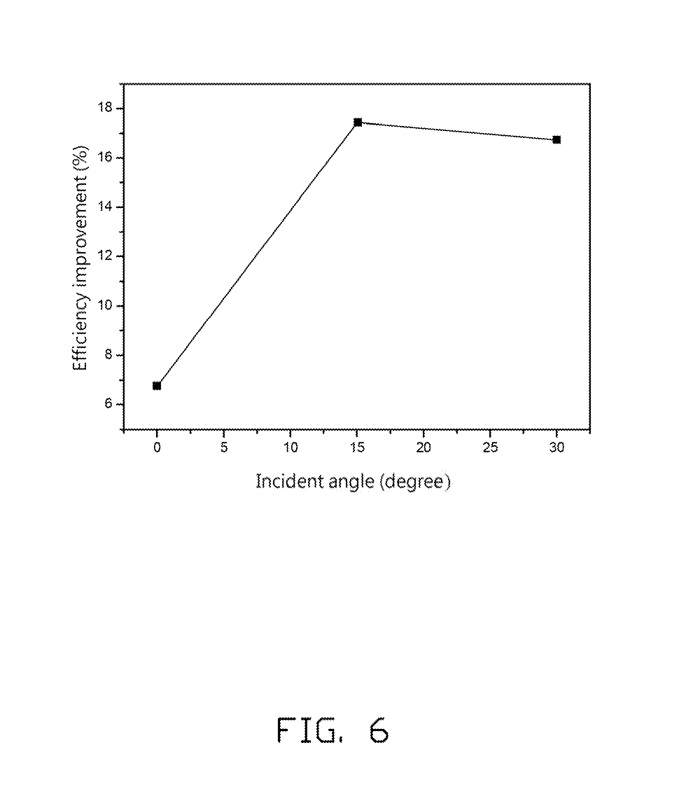

FIG. 6 illustrates improvements of light-absorbing efficiencies of the sample created by the above embodiment relative to the sample before forming the optical film, at different light incident angles. In the embodiment, the light-absorbing efficiency of the sample before forming the optical film is referred to as initial light-absorbing efficiency, and the improvement of light-absorbing efficiency of the sample is calculated by a formula;

the improvement of light-absorbing efficiency of the sample =(light-absorbing efficiencies of the sample having the optical film−initial light-absorbing efficiency)/initial light-absorbing efficiency×100%.

The results show that light-absorbing efficiencies of the sample having the optical film under non-zero light incident angles on the light receiving surface 101 is greatly improved.

The embodiments shown and described above are only examples. Many details are often found in the art such as the other features of a solar cell. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A solar cell comprising:
a solar cell panel comprising a light receiving surface; and
an optical film formed on the light receiving surface, the optical film comprising a birefringent material having a relative refraction index of about 1.05 to about 2.5 and a transparent adhesive.

2. The solar cell of claim 1, wherein the solar cell panel is selected from the group consisting of a silicon semiconductor solar cell panel, a cadmium telluride thin film solar cell panel, a copper indium gallium selenide thin film solar cell panel, a III-V compound semiconductor solar cell panel, and an organic material solar cell panel.

3. The solar cell of claim 2, wherein the light receiving surface is a planar surface.

4. The solar cell of claim 2, wherein the light receiving surface is etched to be a randomly rough surface.

5. The solar cell of claim 2, wherein the light receiving surface is covered by regular three-dimensional structures.

6. The solar cell of claim 1, wherein the birefringent material changes a transmission direction of light and enables non-perpendicular incident light beams to pass through the optical film to be perpendicularly incident on the light receiving surface.

7. The solar cell of claim 6, wherein the birefringent material is a liquid crystal.

8. The solar cell of claim 7, wherein the liquid crystal is a liquid crystal polymer.

9. The solar cell of claim 6, wherein the birefringent material is one or more selected from the group consisting of quartz, calcite, and ruby.

10. The solar cell of claim 1, wherein the optical film has a thickness of about 1 nm to about 500 μm.

11. A method for manufacturing a solar cell, comprising:
providing a solar cell panel comprising a light receiving surface;
preparing a coating solution comprising a birefringent material having a relative refraction index of about 1.05 to about 2.5, a transparent adhesive, and an organic solvent;
coating the light receiving surface with the coating solution, thereby forming a liquid layer of the coating solution on the light receiving surface; and
curing the liquid layer to form an optical film on the light receiving surface.

12. The method of claim 11, wherein within the coating solution, the birefringent material has a weight percentage in a range from about 0.1% to about 33%.

13. The method of claim 12, wherein the birefringent material is a liquid crystal.

14. The method of claim 13, wherein the liquid crystal has a weight percentage in a range from about 0.1% to about 5% base on a total weight of the coating solution.

15. The method of claim 13, wherein the liquid crystal is a liquid crystal polymer.

16. The method of claim 12, wherein the birefringent material is one or more selected from the group consisting of quartz, calcite, and ruby.

17. The method of claim 12, wherein the liquid layer of the coating solution has a thickness of about 5 nm to about 800 μm.

18. The method of claim 11, wherein the solar cell panel is selected from the group consisting of a silicon semiconductor solar cell panel, a cadmium telluride thin film solar cell panel, a copper indium gallium selenide thin film solar cell panel, a III-V compound semiconductor solar cell panel, and an organic material solar cell panel.
